(19) United States
(12) Patent Application Publication
(10) Pub. No.: US 2025/0364062 A1
(43) Pub. Date: Nov. 27, 2025

(54) PROGRAM SUSPEND-RESUME OPERATIONS IN A MEMORY DEVICE

(71) Applicant: Micron Technology, Inc., Boise, ID (US)

(72) Inventors: Narayanan Ramanan, Telengana (IN); Keng Gee Ng, Singapore (SG); Shyam Sunder Raghunathan, Singapore (SG); Sanjoy Jena, Singapore (SG); Ragul S, Telangana (IN); Abinaya Roshini Natarajan, Singapore (SG)

(21) Appl. No.: 19/214,412

(22) Filed: May 21, 2025

Related U.S. Application Data
(60) Provisional application No. 63/651,032, filed on May 23, 2024.

(51) Int. Cl. G11C 16/34; G11C 16/10; G11C 16/12

(52) U.S. Cl. CPC G11C 16/3459; G11C 16/102; G11C 16/12

(57) ABSTRACT

A memory device includes a memory array of memory cells and control logic operatively coupled with the memory array. The control logic causes a program verify operation to be performed on a set of memory cells of the memory array in response to receiving a suspend command while programming the set of memory cells. The control logic reduces a target pre-program verify voltage or increases a target pre-program verify boost voltage for the set of memory cells in response to receiving a resume command. The control logic causes the program verify operation to again be performed on the set of memory cells before resuming programming the set of memory cells.

### CLAIM OF PRIORTY

The present application claims the benefit under 35 U.S.C. § 119(e) of U.S. Provisional Patent Application No. 63/651,032, filed May 23, 2024, which is incorporated by this reference herein.

### TECHNICAL FIELD

Embodiments of the disclosure are generally related to memory sub-systems, and more specifically, relate to program suspend-resume operations in a memory device of a memory sub-system to improve programming time and avoid overprogramming.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of some embodiments of the disclosure.

FIG. 1A illustrates an example computing system that includes a memory sub-system in accordance with some embodiments.

FIG. 1B is a block diagram of a memory device in communication with a memory sub-system controller of a memory sub-system according to an embodiment.

FIG. 2A-2C are schematics of portions of an array of memory cells as could be used in a memory of the type described with reference to FIG. 1B according to an embodiment.

FIG. 3 is a diagrammatic illustration that depicts memory cell populations for a triple-level cell (TLC) memory according to at least one embodiment.

FIG. 4 is a timing diagram depicting a portion of a programming operation to program selected TLC memory cells to target threshold voltages according to an embodiment.

FIG. 5A and FIG. 5B are diagrammatic illustrations that depict a population of memory cells during a programming operation to program selected memory cells to a target voltage using selective slow program convergence according to at least one embodiment.

FIG. 6 is a schematic of portions of a page buffer that can be used in a memory of the type described with reference to FIGS. 1A-1B according to some embodiments.

FIG. 7A is a diagrammatic illustration that depicts charge loss of memory cells that generally cause misclassification after a threshold voltage (Vt) of the memory cells drop below a pre-program verify (PPV) voltage according to some embodiments.

FIG. 7B is a diagrammatic illustration that depicts charge loss of memory cells that generally cause misclassification after the Vt of the memory cells drop between the PPV voltage and a program verify (PV) voltage according to some embodiments.

FIG. 8 is a flow diagram of an example method of compensating for the cells classified as per FIG. 7A so as to avoid misclassification according to some embodiments.

FIG. 9 is a flow diagram of an example method of compensating for the cells classified as per FIG. 7B as to avoid voltage overshoot according to some embodiments.

FIG. 10 is a flow diagram of an example method of selectively programming wordlines based on likelihood of charge loss or program step voltage to provide additional protection against voltage overshoot according to some embodiments.

FIG. 11 is a block diagram of an example computer system in which embodiments of the present disclosure can operate.

### DETAILED DESCRIPTION

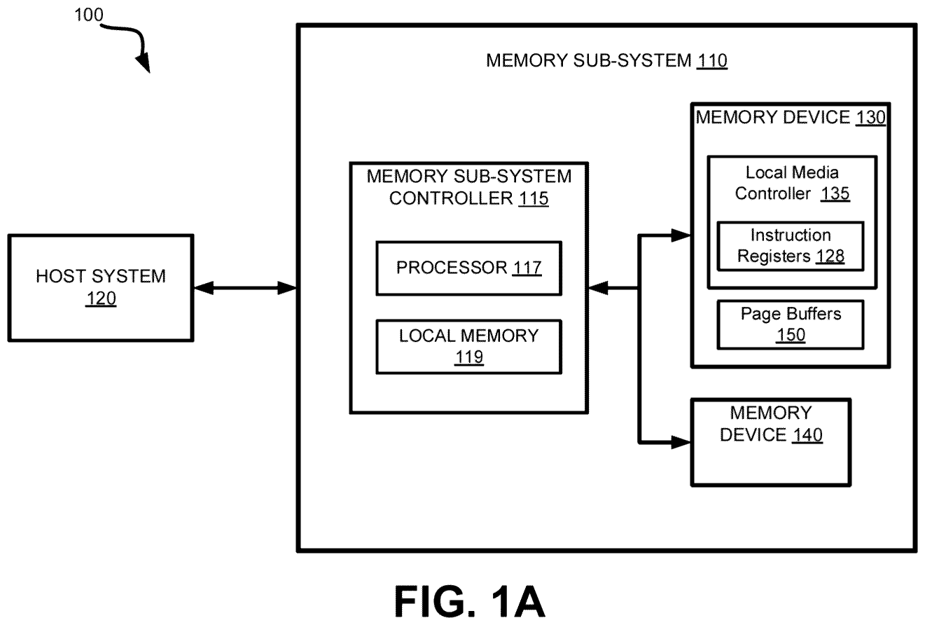

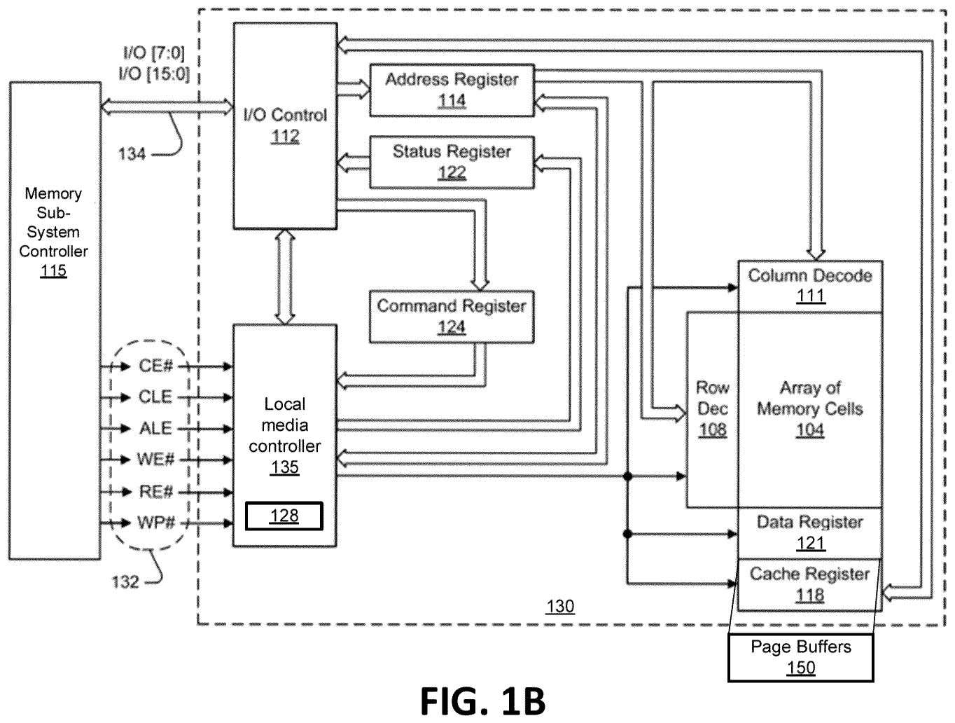

Embodiments of the present disclosure are directed to memory devices employing program suspend-resume operations to improve programming time and avoid overprogramming. A memory device can be a non-volatile memory device. One example of non-volatile memory devices is a negative-and (NAND) memory device, which is an example of a flash memory device. Other examples of non-volatile memory devices are described below in conjunction with FIG. 1A. These memory devices include memory cells in which to store data. For example, changes in threshold voltage (Vt) of the memory cells, through programming (which is often referred to as writing) of charge storage structures (e.g., floating gates or charge traps) or other physical phenomena (e.g., phase change or polarization), determine the data state (or data value) of each memory cell.

In programming memory, memory cells can generally be programmed as single-level cells (SLC) or multiple-level cells (MLC). Single-level cells can use a single memory cell to represent one digit (e.g., bit) of data. For example, in SLC, a Vt of 2.5V can indicate a programmed memory cell (e.g., representing a logical 0) while a Vt of −0.5V can indicate an erased cell (e.g., representing a logical 1). As an example, the erased state in SLC can be represented by any threshold voltage less than or equal to 0V, while the programmed data state can be represented by any threshold voltage greater than 0V. Multiple-level cells use more than two Vt ranges, where each Vt range indicates a different data state. A margin (e.g., a certain number of volts) such as a dead space can separate adjacent Vt ranges to facilitate differentiating between data states. Multiple-level cells can take advantage of the analog nature of traditional non-volatile memory cells by assigning a bit pattern to a specific Vt range.

In programming MLC memory, data values are often programmed using more than one pass, e.g., programming one or more digits in each pass. For example, in four-level MLC (typically referred to simply as MLC), a first digit, e.g., a least significant bit (LSB), which is often referred to as lower page (LP) data, can be programmed to the memory cells in a first pass, thus resulting in two (e.g., first and second) threshold voltage ranges. Subsequently, a second digit, e.g., a most significant bit (MSB), which is often referred to as upper page (UP) data can be programmed to the memory cells in a second pass, typically moving some portion of those memory cells in the first threshold voltage range into a third threshold voltage range, and moving some portion of those memory cells in the second threshold voltage range into a fourth threshold voltage range. Similarly, eight-level MLC (typically referred to as TLC) can represent a bit pattern of three bits, including a first digit, e.g., a least significant bit (LSB) or lower page (LP) data; a second digit, e.g., upper page (UP) data; and a third digit, e.g., a most significant bit (MSB) or extra page (XP) data. In operating TLC, the LP data can be programmed to the memory cells in a first pass, resulting in two threshold voltage ranges, followed by the UP data and the XP data in a second pass, resulting in eight threshold voltage ranges. Similarly, sixteen-level MLC (typically referred to as QLC) can represent a bit pattern of four bits, and 32-level MLC (typically referred to as PLC) can represent a bit pattern of five bits.

To program a group of memory cells to each Vt state of SLC or MLC memory, according to some embodiments, a local media control (e.g., control logic) of some memory devices causes different voltage levels to be applied to data lines (or bitlines) that causes selected memory cell(s), such as a population of memory cells, to be programmed. In these embodiments, the control logic can send a control signal to a signal driver that is selectively connected between a page buffer and a bitline. The page buffer can provide voltage levels to the signal driver that the signal driver can use, when turned on by the control signal, to generate a voltage on the bitline that programs a selected memory cell of the group of memory cell(s). These voltage levels can vary in voltage depending on a level (or speed) of programming to occur, as will be explained.

In some embodiments, programming the memory cells can occur in programming schemes referred to as selective slow programming convergence (SSPC). In SSPC programming, for example, memory cells nearer to their respective intended data states are programmed more slowly (e.g., partially enabled for programming) compared to memory cells farther from their respective intended data states (e.g., fully enabled for programming) while receiving a same voltage level at their respective control gates. A target voltage can correspond to a minimum threshold voltage for a target Vt level, which can be referred to as the program verify (PV) voltage for the target voltage. A pre-program verify (PPV) voltage can be selected to be less than the PV voltage to enable SSPC programming between the PV voltage and the PPV voltage.

Depending on how close memory cells are from the target voltage, the page buffers can be directed to provide a bias voltage to the memory cells (via signal drivers) to selectively control the voltage levels actually being applied to the group or population of memory cells. As the memory cells get closer to their respective target voltages, the applied bias voltages generally increase so that the actual program pulse voltages decrease, slowing down the programming rate. For example, three bias voltages can correspond to at least three voltage levels, including non-SSPC programming (e.g., before reaching the PPV voltage), SSPC programming performed between the PPV and PV voltage levels, and inhibited from programming. Of these three bias voltages, any given page buffer may provide one of the bias voltages at any given time depending on a phase of SSPC-related programming in which the memory cells are being programmed by that particular page buffer. These bias voltages can also be applied during program verify operations associated with determining how close the memory cells have been programmed to the target voltage, which can then lead to switching to apply a different, perhaps slower programming, voltage bias level for a subsequent phase of SSPC programming.

In most memory devices, a read operation is faster than an program operation, and read operations can be given priority over program operations. For this reason, program operations are often repeatedly interrupted when a host system (or coupled memory sub-system controller, e.g., processing device) sends a suspend command in order to temporarily suspend the program operation in favor of performing a read or other non-program memory operation. Upon completion of the read operation, a program resume command can be issued to resume and complete a program operation that had been suspended. In certain memory devices, information related to SSPC-classified cells at suspend is lost and it can be difficult to determine how to resume the programming of such memory cells. Thus, in most cases, a program verify (PVY) is performed upon resuming the program operation to determine a threshold voltage (Vt) level of memory cells being programmed.

In certain memory devices, charge loss occurs during a program suspend operation while one or more read operations, for example, are being performed. As a result, after a program verify is performed on resume, memory cells can often be misclassified into the wrong category (e.g., program, SSPC, or inhibit) compared to classification of those memory cells when the program operation was suspended. As a result, misclassified memory cells can be programmed with excessive electric field upon resume of the program operation, resulting in Vt overshoot of those memory cells, and state-width widening to the memory cells due to such overprogramming.

In some of these memory devices, when programming is resumed, the program step voltage (Vpgm-step) of a programming pulse is reduced (e.g., a pull-back Vpgm-step) for the memory cells to avoid such overprogramming. While this approach helps reduce the damage from the subsequent programming pulse in response to a program resume command, this approach also degrades the total programming time (Tprog) for these memory cells as programming takes longer to finish, e.g., some (or many) memory cells will be programmed slower due to reducing the program voltage step for all memory cells being programmed.

Aspects of the present disclosure address the above and other deficiencies by modifying the next program verify and program pulse for a set of the memory cells to be programmed upon receipt of a resume command, and reverting the change thereafter. For a subset of memory cells that fall within a threshold amount below the PPV voltage due to charge loss, restoring the correct SSPC classification can help avoid overprogramming. In these embodiments, for example, a target PPV voltage level may be reduced or a target pre-program verify boost voltage may be increased, enabling the subset of memory cells to be properly classified as SSPC cells and thus be programmed at the intended slower SSPC rate. After a first programming pulse is applied to this subset of memory cells, the PPV voltage (or pre-program verify boost voltage) can be reset to an original voltage.

In other embodiments, when the memory cells being programmed at resume did not undergo a program verify at suspend, the memory device can lose information about memory cells that had been programmed to the inhibit voltage level (e.g., programmed beyond the PV voltage level). In such embodiments, the charge losses can cause a subset of the memory cells to be misclassified as between PPV and PV voltage levels upon performing a program verify at the beginning of a resume operation. The result can be to over-program such misclassified cells, e.g., to beyond the PV voltage plus a half gate-step voltage (PV+0.5 GS). In some embodiments, to prevent this undesired result, the memory device can cause, in response to receiving a resume command, a target bitline voltage of the set of memory cells to be increased to slow down programming the set of memory cells, e.g., slower than originally intended with SSPC voltage on the bitlines. In embodiments, these target bitline voltages are restored to normal levels for subsequent programming pulses after the resume operation has completed.

In various embodiments, the voltage overshoot of misclassified memory cells at the subsequent pulse (after resume) is a function of the likelihood of charge loss and the program step voltage (Vpgm-step) of the programming pulse. Both charge loss and the program step voltage can vary across different WLs, and can be limited by mechanisms at each memory cell. Thus, to avoid overprogramming memory cells based on these criteria, the memory device can further vary the reduced program step voltages applied to groups of WLs to minimize the performance impact whenever possible, e.g., in some embodiments, according to a gate-step voltage of these memory cells. More specifically, the memory device can apply a lower reduced program step voltage to WLs that have a lower gate-step voltage and apply a higher reduced program step voltage to WLs that have a higher gate-step voltage. In embodiments, the voltage amplitude of a subsequent programming pulse during the SSPC-based programming (e.g., a second programming pulse after resume) can be restored to an original program step voltage.

Therefore, advantages of the systems, devices, and methods implemented in accordance with some embodiments of the present disclosure include, but are not limited to, selective application of SSPC-based programming techniques upon resuming programming that provide a selective improvement to memory cells that are misclassified within the SSPC programming framework. The benefits of these selective improvements include avoiding over-programming of some misclassified memory cells, thus avoiding a corresponding Vt state width degradation on the memory cells. Further, the benefits include avoiding applying the same reduced voltage to all the memory cells upon program resume, thus also reducing the programming time, e.g., avoiding some of the programming time increase that is caused by applying the same reduced program voltage step to all wordlines. Other advantages will be apparent to those skilled in the art of memory programming, to include selective slow program convergence and program suspend-resume operations, associated with a memory device discussed hereinafter.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such media or memory devices. The memory sub-system 110 can be a storage device, a memory module, or a hybrid of a storage device and memory module.

The memory device 130 can be a non-volatile memory device. One example of non-volatile memory devices is a negative-and (NAND) memory device. A non-volatile memory device is a package of one or more dice. Each die can include one or more planes. Planes can be groups into logic units (LUN). For some types of non-volatile memory devices (e.g., NAND devices), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1,” or combinations of such values.

The memory device 130 can be made up of bits arranged in a two-dimensional or three-dimensional grid, also referred to as a memory array. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface, Open NAND Flash Interface (ONFI) interface, or some other interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130,140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which includes a raw memory device 130 having control logic (e.g., local media controller 135) on the die and a controller (e.g., memory sub-system controller 115) for media management within the same memory device package. An example of a managed memory device is a managed NAND (MNAND) device.

In some embodiments, the memory device 130 includes page buffers 150, which can be used to program data to the memory cells of the memory device 130 and to read the data out of the memory cells. Control logic of the local media controller 135 can be configured to coordinate the timing and manner of applying one of three different voltage biases for selective slow program convergence voltage programming, as will be explained in detail. These three different bias voltages can be associated with, for example, program verify pass voltage (e.g., inhibit bias voltage), a selective slow program convergence voltage (e.g., PPV), and a program verify fail voltage (e.g., ground or Vss).

In at least some embodiments, the local media controller 135 (e.g., control logic) includes instruction registers 128, which represent computer-usable memory for storing computer-readable instructions. For some embodiments, the instruction registers 128 represent firmware. Alternatively, the instruction registers 128 represent a grouping of memory cells, e.g., reserved block(s) of memory cells, of an array of memory cells 104 (see FIG. 1A).

FIG. 1B is a simplified block diagram of a first apparatus, in the form of a memory device 130, in communication with a second apparatus, in the form of a memory sub-system controller 115 of a memory sub-system (e.g., the memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), can be a memory controller or other external host device.

The memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line can be associated with more than one logical row of memory cells and a single data line can be associated with more than one logical column. Memory cells (not shown in FIG. 1B) of at least a portion of the array of memory cells 104 are capable of being programmed to one of at least two target data states.

Row decode circuitry 108 and column decode circuitry 111 are provided to decode address signals. Address signals are received and decoded to access the array of memory cells 104. The memory device 130 also includes input/output (I/O) control circuitry 112 to manage input of commands, addresses and data to the memory device 130 as well as output of data and status information from the memory device 130. An address register 114 is in communication with the I/O control circuitry 112 and row decode circuitry 108 and column decode circuitry 111 to latch the address signals prior to decoding. A command register 124 is in communication with the I/O control circuitry 112 and the local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations, and/or crase operations) on the array of memory cells 104. The local media controller 135 is in communication with row decode circuitry 108 and column decode circuitry 111 to control the row decode circuitry 108 and column decode circuitry 111 in response to the addresses.

The local media controller 135 is also in communication with a cache register 118 and a data register 121. The cache register 118 latches data, either incoming or outgoing, as directed by the local media controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in the cache register 118 from the I/O control circuitry 112. During a read operation, data can be passed from the cache register 118 to the I/O control circuitry 112 for output to the memory sub-system controller 115; then new data can be passed from the data register 121 to the cache register 118. The cache register 118 and/or the data register 121 can form (e.g., can form at least a portion of) the page buffers 150 of the memory device 130. The page buffers 150 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to the memory sub-system controller 115.

The memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) can be used in the various embodiments.

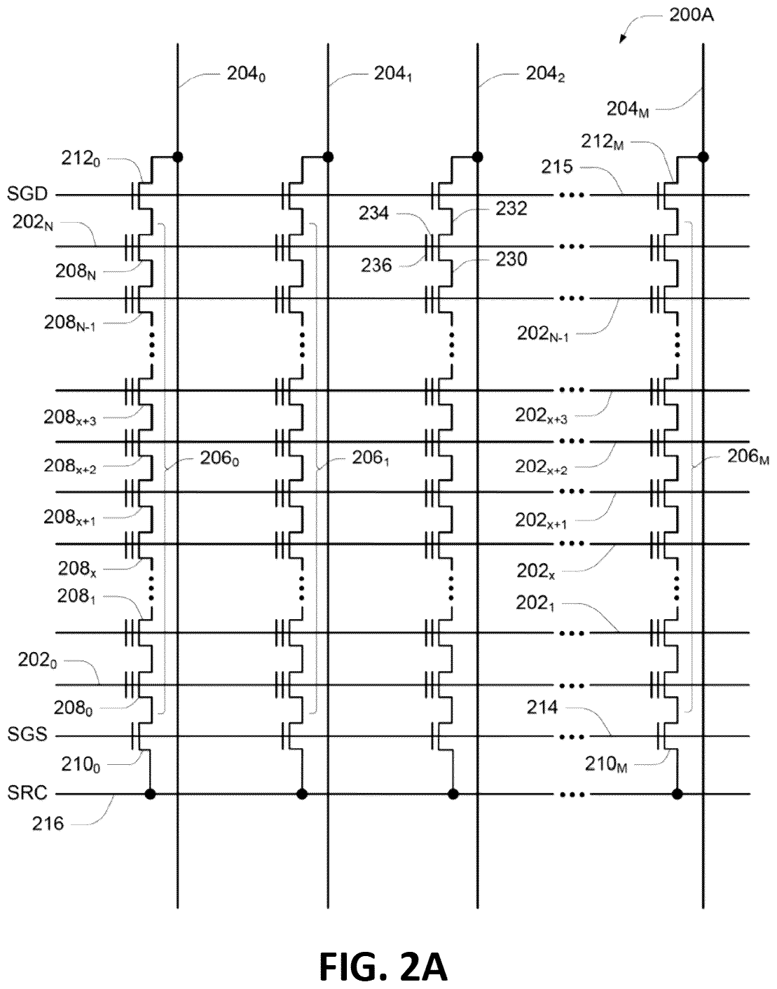

FIG. 2A-2C are schematics of portions of an array of memory cells 200A, such as a NAND memory array, as could be used in a memory of the type described with reference to FIG. 1B according to an embodiment, e.g., as a portion of the array of memory cells 104. Memory array 200A includes access lines, such as wordlines 2020 to 202N, and data lines, such as bitlines 2040 to 204M. The wordlines 202 can be connected to global access lines (e.g., global wordlines), not shown in FIG. 2A, in a many-to-one relationship. For some embodiments, memory array 200A can be formed over a semiconductor that, for example, can be conductively doped to have a conductivity type, such as a p-type conductivity, e.g., to form a p-well, or an n-type conductivity, e.g., to form an n-well.

Memory array 200A can be arranged in rows (each corresponding to a wordline 202) and columns (each corresponding to a bitline 204). Each column can include a string of series-connected memory cells (e.g., non-volatile memory cells), such as one of NAND strings 2060 to 206M. Each NAND string 206 can be connected (e.g., selectively connected) to a common source (SRC) 216 and can include memory cells 2080 to 208N. The memory cells 208 can represent non-volatile memory cells for storage of data. The memory cells 208 of each NAND string 206 can be connected in series between a select gate 210 (e.g., a field-effect transistor), such as one of the select gates 2100 to 210M (e.g., that can be source select transistors, commonly referred to as select gate source), and a select gate 212 (e.g., a field-effect transistor), such as one of the select gates 2120 to 212M (e.g., that can be drain select transistors, commonly referred to as select gate drain). Select gates 2100 to 210M can be commonly connected to a select line 214, such as a source select line (SGS), and select gates 2120 to 212M can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 2080 of the corresponding NAND string 206. For example, the drain of select gate 2100 can be connected to memory cell 2080 of the corresponding NAND string 2060. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 2120 can be connected to the bitline 2040 for the corresponding NAND string 2060. The source of each select gate 212 can be connected to a memory cell 208N of the corresponding NAND string 206. For example, the source of select gate 2120 can be connected to memory cell 208N of the corresponding NAND string 2060. Therefore, each select gate 212 can be configured to selectively connect a corresponding NAND string 206 to the corresponding bitline 204. A control gate of each select gate 212 can be connected to select line 215.

The memory array 200A in FIG. 2A can be a quasi-two-dimensional memory array and can have a generally planar structure, e.g., where the common source 216, NAND strings 206 and bitlines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202N and selectively connected to even bitlines 204 (e.g., bitlines 2040, 2042, 2044, etc.) can be one physical page of the memory cells 208 (e.g., even memory cells) while memory cells 208 commonly connected to wordline 202N and selectively connected to odd bitlines 204 (e.g., bitlines 2041, 2043, 2045, etc.) can be another physical page of the memory cells 208 (e.g., odd memory cells).

Although bitlines 2043-2045 are not explicitly depicted in FIG. 2A, it is apparent from the figure that the bitlines 204 of the array of memory cells 200A can be numbered consecutively from bitline 2040 to bitline 204M. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 2020-202N (e.g., all NAND strings 206 sharing common wordlines 202). Unless expressly distinguished, a reference to a page of memory cells herein refers to the memory cells of a logical page of memory cells. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory of the type described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B can incorporate vertical structures which can include semiconductor pillars where a portion of a pillar can act as a channel region of the memory cells of NAND strings 206. The NAND strings 206 can be each selectively connected to a bitline 2040-204M by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bitline 204. Subsets of NAND strings 206 can be connected to their respective bitlines 204 by biasing the select lines 2150-215K to selectively activate particular select transistors 212 each between a NAND string 206 and a bitline 204. The select transistors 210 can be activated by biasing the select line 214. Each wordline 202 can be connected to multiple rows of memory cells of the memory array 200B. Rows of memory cells that are commonly connected to each other by a particular wordline 202 can collectively be referred to as tiers.

FIG. 2C is a further schematic of a portion of an array of memory cells 200C as could be used in a memory of the type described with reference to FIG. 1B, e.g., as a portion of the array of memory cells 104. Like numbered elements in FIG. 2C correspond to the description as provided with respect to FIG. 2A. The array of memory cells 200C can include strings of series-connected memory cells (e.g., NAND strings) 206, access (e.g., word) lines 202, data (e.g., bit) lines 204, select lines 214 (e.g., source select lines), select lines 215 (e.g., drain select lines) and a source 216 as depicted in FIG. 2A. A portion of the array of memory cells 200A can be a portion of the array of memory cells 200C, for example.

FIG. 2C depicts groupings of NAND strings 206 into blocks of memory cells 250, e.g., blocks of memory cells 2500-250L. Blocks of memory cells 250 can be groupings of memory cells 208 that can be erased together in a single erase operation, sometimes referred to as erase blocks. Each block of memory cells 250 can represent those NAND strings 206 commonly associated with a single select line 215, e.g., select line 2150. The source 216 for the block of memory cells 2500 can be a same source as the source 216 for the block of memory cells 250L. For example, each block of memory cells 2500-250L can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 2500-250L.

The bitlines 2040-204M can be connected (e.g., selectively connected) to a buffer portion 240, which can be a portion of the page buffer of the memory device 130. The buffer portion 240 can correspond to a memory plane (e.g., the set of blocks of memory cells 2500-250L). The buffer portion 240 can include sense circuits (which can include sense amplifiers) for sensing data values indicated on respective bitlines 204.

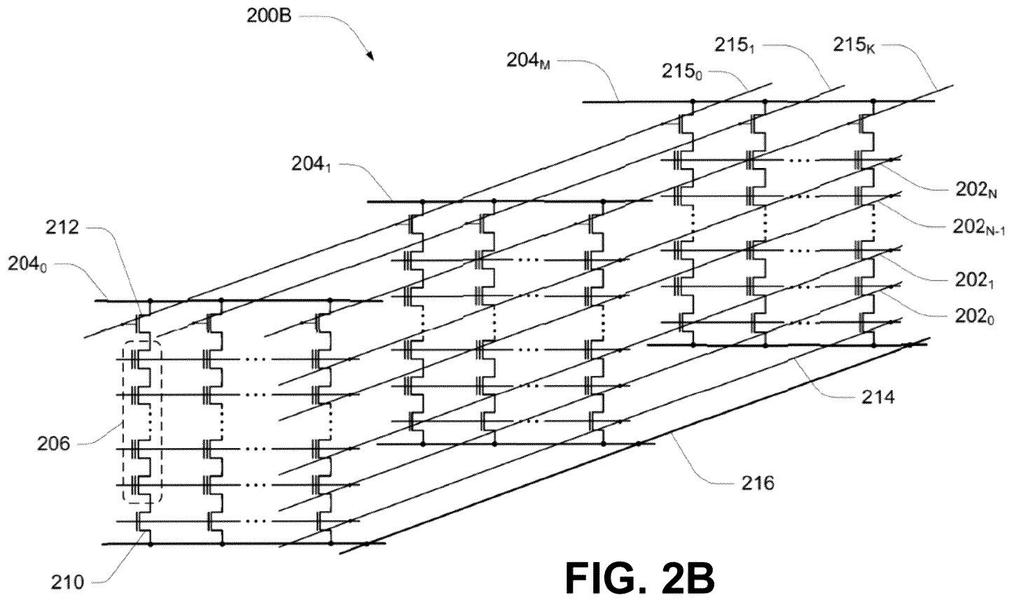

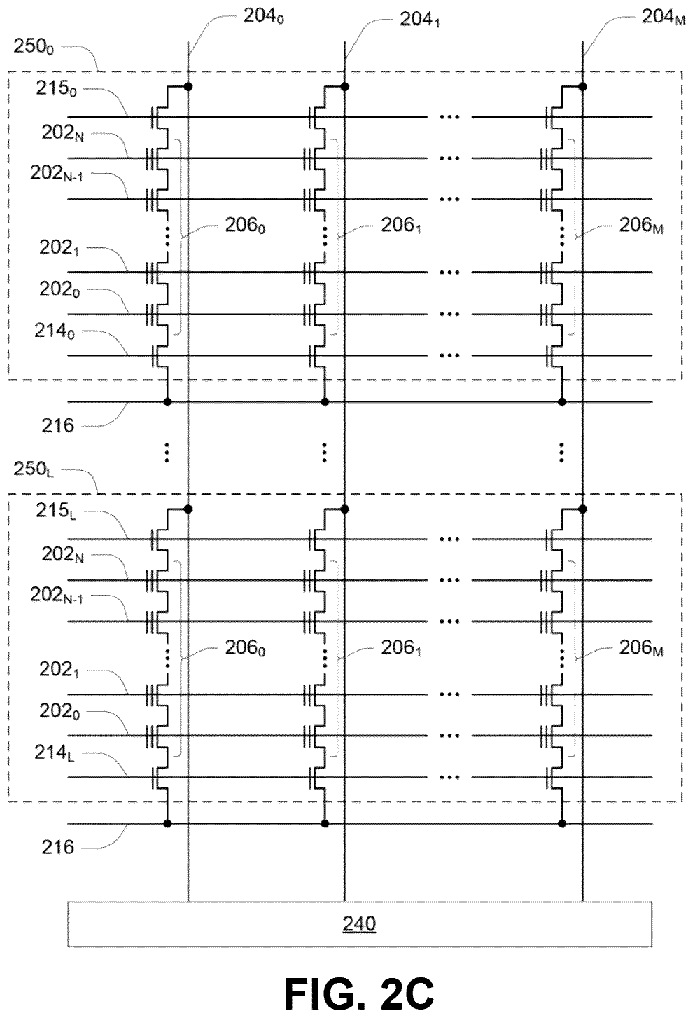

FIG. 3 is a diagrammatic illustration that depicts memory cell populations for a triple-level cell (TLC) memory according to at least one embodiment. For simplicity, FIG. 3 and the following FIG. 4 will presume programming operations for TLC memory cells, e.g., eight-level memory cells representing data states L0, L1, L2, L3, L4, L5, L6, and L7 using eight threshold voltage ranges, each representing a data state corresponding to a bit pattern of three digits. While discussed in reference to TLC memory cells, programming operations performed on lower storage density memory cells, e.g., SLC (two data states) or higher storage density memory cells, e.g., QLC (16 data states) or PLC (32 data states) memory cells, are equally applicable.

In this example, the population of memory cells 310 can be erased memory cells and represent a logical data value of ‘111’, the population of memory cells 311 can represent a logical data value of ‘011’, the population of memory cells 312 can represent a logical data value of ‘001’, the population of memory cells 313 can represent a logical data value of ‘101’, the population of memory cells 314 can represent a logical data value of ‘100’, the population of memory cells 315 can represent a logical data value of ‘000’, the population of memory cells 316 can represent a logical data value of ‘010’, and the population of memory cells 317 can represent a logical data value of ‘110’, where the right-most digit can represent the lower page data for a memory cell having a threshold voltage within the threshold voltage range of its respective population of memory cells, the center digit can represent the upper page data for that memory cell, and the left-most digit can represent the extra page data for that memory cell. Although a specific example of binary representation is provided, embodiments can use other arrangements of bit patterns to represent the various data states.

A read window between the population of memory cells 310 and the population of memory cells 311 is indicated at 320, which is the distance (e.g., in voltage) between adjacent Vt distributions for the memory cells representing data states L0 and L1. A read window between the population of memory cells 311 and the population of memory cells 312 is indicated at 321, which is the distance (e.g., in voltage) between adjacent Vt distributions for the memory cells representing data states L1 and L2. Likewise, a read window between the population of memory cells 312, 313, 314, 315, and 316, and the population of memory cells 313, 314, 315, 316, and 317 is indicated at 322, 323, 324, 325, and 326, respectively, which is the distance between adjacent Vt distributions for the memory cells representing data states L2, L3, L4, L5, L6, and L7. A read window budget (RWB) can refer to a cumulative value of read windows for a group of programmed cells (e.g., one or more pages of cells). In this example, the RWB can be the cumulative value (e.g., in voltage) of the seven read windows 320-326 between the eight Vt distributions.

FIG. 4 is a timing diagram depicting a portion of a programming operation to program selected TLC memory cells to target Vt levels L0 to L7 (e.g., as illustrated in FIG. 3) according to an embodiment. Once a selected memory cell has been programmed to its target Vt level, the memory cell is inhibited from further programming. Prior to time t0, memory cells selected for programming can be erased such that the selected memory cells each have a threshold voltage corresponding to level L0. At time t0, a first program pulse is applied to a selected access line (e.g., 202 of FIG. 2A) connected to the control gates (e.g., 236) of the selected memory cells (e.g., 208). After the first program pulse, a program verify operation can be performed to verify whether a target population of the selected memory cells has been programmed to level L1 or L2. At time t1, a second program pulse, e.g., higher than the first program pulse, is applied to the selected access line connected to the control gates of the selected memory cells. After the second program pulse, a program verify operation can be performed to verify whether target populations of the selected memory cells have been programmed to Vt level L1 or L2.

At time t2, a third program pulse, e.g., higher than the second program pulse, is applied to the selected access line connected to the control gates of the selected memory cells. After the third program pulse, a program verify operation can be performed to verify whether target populations of the selected memory cells have been programmed to level Vt L1, L2, or L3. At time t3, a fourth program pulse, e.g., higher than the third program pulse, is applied to the selected access line connected to the control gates of the selected memory cells. After the fourth program pulse, a program verify operation can be performed to verify whether target populations of the selected memory cells have been programmed to Vt level L2, L3, or L4. At time t4, a fifth program pulse, e.g., higher than the fourth program pulse, is applied to the selected access line connected to the control gates of the selected memory cells. After the fifth program pulse, a program verify operation can be performed to verify whether target populations of the selected memory cells have been programmed to Vt level L2, L3, L4, or L5.

At time t5, a sixth program pulse, e.g., higher than the fifth program pulse, is applied to the selected access line connected to the control gates of the selected memory cells. After the sixth program pulse, a program verify operation can be performed to verify whether target populations of the selected memory cells have been programmed to Vt level L3, L4, L5, or L6. At time t6, a seventh program pulse, e.g., higher than the sixth program pulse, is applied to the selected access line connected to the control gates of the selected memory cells. After the seventh program pulse, a program verify operation can be performed to verify whether target populations of the selected memory cells have been programmed to Vt level L3, L4, L5, L6, or L7. At time t7, an eighth program pulse, e.g., higher than the seventh program pulse, can be applied to the selected access line connected to the control gates of the selected memory cells and the process can repeat until the selected memory cells have been programmed to their target levels.

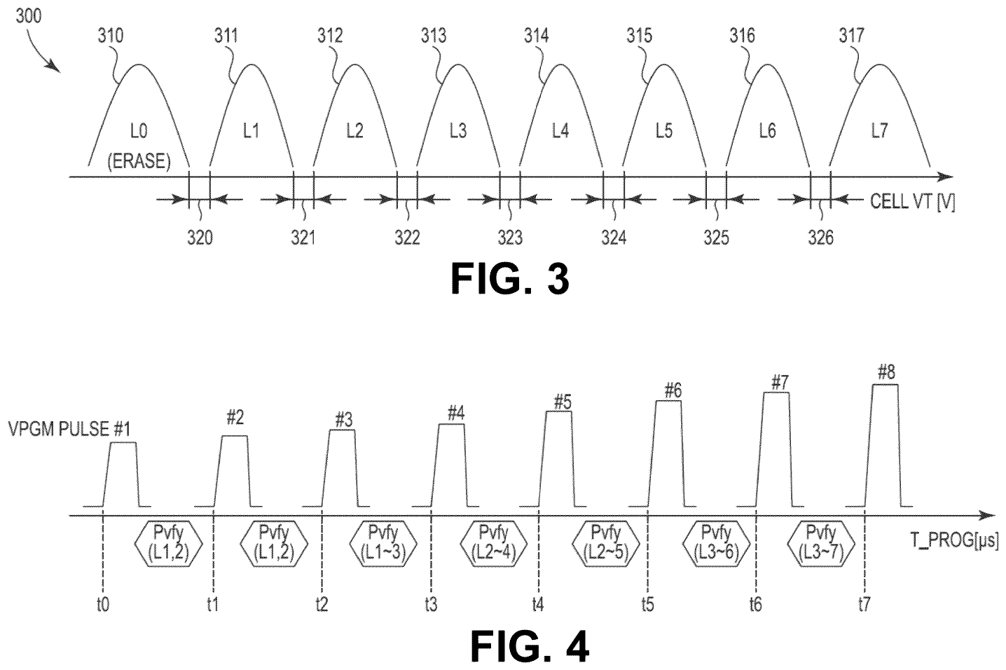

FIG. 5A and FIG. 5B are diagrammatic illustrations that depict a population of memory cells 500 during a programming operation to program selected memory cells to a target voltage (e.g., a target Vt level) using selective slow program convergence according to at least one embodiment. FIG. 5A depicts a population of memory cells 500 after a particular program pulse of a programming operation to program selected memory cells to a target voltage (or Vt level) as indicated by a population of memory cells 502. The use of different voltage levels on data lines to be enabled for programming can occur in programming schemes known as selective slow programming convergence (SSPC), where memory cells nearer to their respective intended data states are programmed more slowly (e.g., partially enabled for programming) compared to memory cells farther from their respective intended data states (e.g., fully enabled for programming) while receiving a same voltage level at their respective control gates. The target voltage may correspond to a minimum threshold voltage for the target level, which can be referred to as a program verify voltage 504 (or PV voltage) for the target voltage. A pre-program verify voltage 504 (or PPV voltage) can be selected to be less than the program verify voltage 504 to enable SSPC programming, which is slower than full enabled programming. Once the population of memory cells 502 is fully programmed, the higher Vt memory cells can extend as high as an upper threshold voltage 506, which in some embodiments, can be approximately the program verify voltage 504 plus a half gate-step voltage (e.g., PV+0.5 GS voltage).

After the particular program pulse, a program verify operation is performed to sense the threshold voltage (Vt) of each memory cell within the population of memory cells 500. Memory cells having a threshold voltage less than the pre-program verify voltage 508 as indicated for example at 510 are biased for non-SSPC programming (e.g., fully enabled for programming). Memory cells having a threshold voltage between the pre-program verify voltage 508 and the program verify voltage 504 as indicated for example at 514 are biased for SSPC programming (e.g., partially enabled for programming) since the memory cells fall within the SSPC range. Memory cells having a threshold voltage greater than the program verify voltage 504 as indicated for example at 516 are inhibited from further programming.

As illustrated in FIG. 5B, with each memory cell within the population of memory cells 500 biased for non-SSPC programming, SSPC programming, or inhibited from programming, a subsequent program pulse is applied to the population of memory cells 500 to increase the threshold voltages of the memory cells to the target level as indicated by the population of memory cells 502. The subsequent program pulse can be immediately subsequent to the particular program pulse. With the memory cells 510 biased for non-SSPC programming, the threshold voltages of the memory cells 510 can be increased above the program verify voltage 504 as indicated by 520 in response to the subsequent program pulse. With the memory cells 512 biased for SSPC programming, the threshold voltages of the memory cells 514 can be increased above the program verify voltage 504 as indicated by 522 in response to the subsequent program pulse. After the subsequent program pulse, a program verify operation is performed to sense the threshold voltage of each memory cell within the population of memory cells 502. In this example, all the memory cells have a threshold voltage greater than the program verify voltage 504 and are inhibited from further programming.

A memory cell can be biased for SSPC programming by biasing the data line connected to the memory cell to a SSPC voltage (e.g., Vt level) during the program pulse. A memory cell can be biased for non-SSPC programming by causing the data line connected to the memory cell to be biased to a non-SSPC voltage level during the program pulse. A memory cell can be inhibited from programming by causing the data line connected to the memory cell to be biased to an inhibit voltage level during the program pulse.

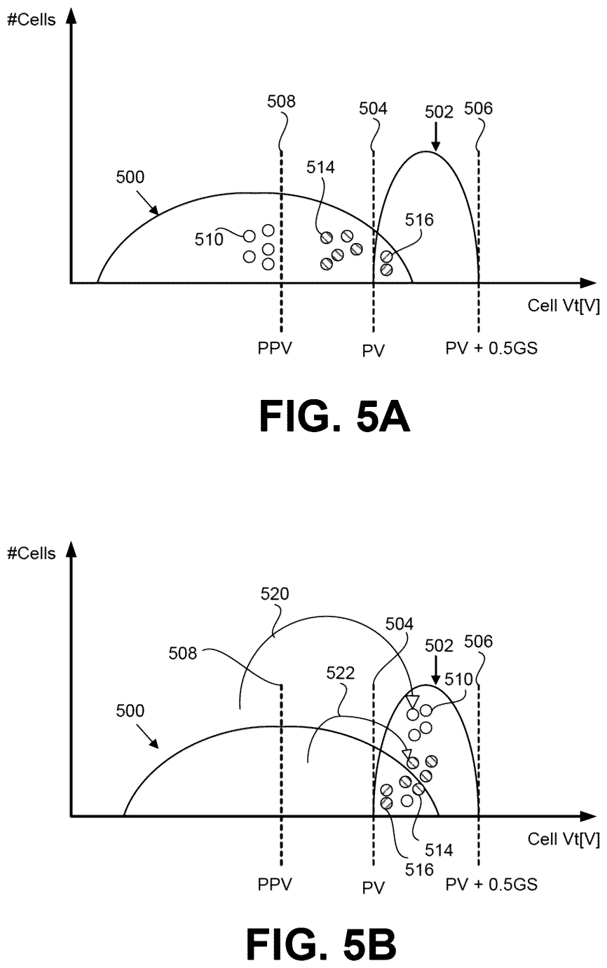

FIG. 6 is a schematic of portions of a page buffer 600 that can be used in a memory of the type described with reference to FIGS. 1A-1B according to some embodiments. In some embodiments, the page buffer 600 is one of the page buffers 150 of FIGS. 1A-1B. The page buffer 600 can be a buffer portion 240 of FIG. 2C. The page buffer 600 includes a selected access line (e.g., wordline) 202, a selected memory cell 208 of a string of series-connected memory cells (not shown), and a selected data line (e.g., bitline) 204, which is attached to the string of series-connected memory cells. The selected access line 202 is connected to the control gate of the selected memory cell 208. The source of the selected memory cell 208 is connected to the common source 216 (e.g., via other memory cells of the string of series-connected memory cells and a respective select gate 210). The drain of the selected memory cell 208 is connected to the selected bitline 204 (e.g., via other memory cells of the string of series-connected memory cells and a respective select gate 212).

In various embodiments, the page buffer 600 also includes transistors 602, 603, 609, 610, 613, 617, 622, 623, 627, 630, 631, 634, 642, 646, 662, 670, 678, and 696, a sense capacitor 654, a sense amplifier latch 686 (e.g., SA latch 686), a first latch 691, and a second latch 692. In some embodiments, the first latch 691 and the second latch 692 are each PDC latches that are coupled with the page buffer circuitry, as will be explained, and can store the inhibit and the PV voltages, respectively (or switched). Transistor 622 can be a p-channel metal-oxide-semiconductor (PMOS) transistor, while transistors 602, 603, 609, 610, 613, 617, 623, 627, 630, 631, 634, 642, 646, 662, 670, 678, and 696 can be n-channel metal-oxide-semiconductor (NMOS) transistors. The sense amplifier latch 686 includes inverters 683 and 684 and transistors 687 and 688 (e.g., NMOS transistors). The bitline 204 is connected to one side of the source-drain path of transistor 602 and one side of the source-drain path of transistor 631. The gate of transistor 631 is connected to a SRC_GATE control signal path 633. The other side of the source-drain path of transistor 631 is connected to the common source 216. The gate of transistor 602 is connected to a DW_GATE control signal path 604.

In some embodiments, the other side of the source-drain path of transistor 602 is connected to one side of the source-drain path of transistor 610 through a DW signal path 606. The gate of transistor 610 (e.g., bitline clamp transistor) is connected to a BLCLAMP control signal path 612. The other side of the source-drain path of transistor 610 is connected to one side of the source-drain path of transistor 630 (e.g., second bitline clamp transistor), one side of the source-drain path of transistor 634, and one side of the source-drain path of transistor 646 through a signal path 614. The gate of transistor 630 is connected to a BLCLAMP2 control signal path 632. The other side of the source-drain path of transistor 630 is connected to one side of the source-drain path of transistor 622 (e.g., upper bias transistor) through a signal path 626. The gate of transistor 622 is connected to one side of the source-drain path of transistor 617 and the gate of transistor 642 (e.g., lower bias transistor) through a BL_SA_OUT signal path 690. The gate of transistor 617 is connected to a SAB_BL_PRE control signal path 619. The other side of the source-drain path of transistor 617 is connected to the input of inverter 683, the output of inverter 684, and one side of the source-drain path of transistor 687 through a SA_OUT signal path 621. The other side of the source-drain path of transistor 622 is connected to a supply node (e.g., VREG2) 618. The gate of transistor 634 is connected to an EN_DATA control signal path 636. The other side of the source-drain path of transistor 634 is connected to one side of the source-drain path of transistor 642 through a signal path 638. The other side of the source-drain path of transistor 642 is connected to a supply node (e.g., VREG0) 639.

The gate of transistor 646 is connected to a TC_ISO control signal path 648. The other side of the source-drain path of transistor 646 is connected to one side of sense capacitor 654, one side of the source-drain path of transistor 662, and the gate of transistor 678 through a TC signal path 650. This first side of the sense capacitor 654 is also connected to a sense node (TC) of the TC signal path 650. In some embodiments, the signal path 614 and the TC signal path 650 are selectively coupled to each other and can, in combination, be referred to as a sense line. Thus, this sense line can include the sense node (TC). The other (or second) side of sense capacitor 654 is connected to a sense capacitor bias node (e.g., BOOST node) 658. The gate of transistor 662 is connected to a BLC1 control signal path 664. The other side of the source-drain path of transistor 662 is connected to one side of the source-drain path of transistor 670, the other side of the source-drain path of transistor 687, one side of the source-drain path of transistor 688, one side of the source-drain path of transistor 603, one side of the source-drain path of transistor 609, one side of the source-drain path of transistor 696, and the gate of transistor 623 through a TDC_INT signal path 666. The gate of transistor 670 is connected to a SEN control signal path 672. The other side of the source-drain path of transistor 670 is connected to one side of the source-drain path of transistor 678 through a signal path 674. The other side of the source-drain path of transistor 678 is connected to a source bias node 682 (e.g., SRC_GND). The transistor 678 can be referred to as a sense transistor having a gate that is connected to the sense node (TC).

The gate of transistor 687 of sense amplifier latch 686 is connected to a DRST_SA control signal path 675. The gate of transistor 688 is connected to a DST_SA signal path 676. The other side of the source-drain path of transistor 688 is connected to the output of inverter 683 and to the input of inverter 684 through a signal path 677. A control input of inverter 683 is connected to a SEN_SAB control signal path 685. A control input of inverter 684 is connected to a LAT_SAB control signal path 689.

The gate of transistor 603 is connected to a TDCINT_DIS control signal path 605. The other side of the source-drain path of transistor 603 is connected to a common or ground (e.g., GND) node 607. The gate of transistor 609 is connected to the other side of the source-drain path of transistor 696, one side of the source-drain path of transistor 623, the first latch 691, and the second latch 692 through a DATA_TRANSFER signal path 693. The other side of the source-drain path of transistor 609 is connected to one side of the source-train path of transistor 613 through a signal path 611. The gate of transistor 613 is connected to an EN_SA control signal path 615. The other side of the source-drain path of transistor 613 is connected to the common or ground node 607. The gate of transistor 696 is connected to a BLC2 control signal path 697. The other side of the source-drain path of transistor 623 is connected to one side of the source-drain path of transistor 627 through a signal path 625. The gate of transistor 627 is connected to an EN_LATCH control signal path 629. The other side of the source-drain path of transistor 627 is connected to the common or ground node 607.

In some embodiments, the page buffer 600 includes a data elaborator 601, which in turn includes a combination of the transistors 609, 613, 623, 627, and 696. The data elaborator 601 can be controlled to manipulate data that is either passed to or read from the first latch 691 or the second latch 692. In some embodiments, the data elaborator 601 includes a parasitic capacitance at a portion of the metal line of DATA_TRANSFER signal path 693 between the data elaborator 601 and the first latch 691.

Control logic (e.g., of the local media controller 135 of FIGS. 1A-1B) can be connected to the SRC_GATE control signal path 633, the DW_GATE control signal path 604, the BLCLAMP control signal path 612, the BLCLAMP2 control signal path 632, the EN_DATA control signal path 636, the TC_ISO control signal path 648, the BLC1 control signal path 664, the SEN control signal path 672, the SAB_BL_PRE control signal path 619, the LAT_SAB control signal path 689, the SEN_SAB control signal path 685, the DRST_SA control signal path 675, the DST_SA control signal path 676, the TDCINT_DIS control signal path 605, the EN_SA control signal path 615, the BCL2 control signal path 697, and the EN_LATCH control signal path 629 to control the operation of the page buffer 600. The control logic can activate transistor 631 to selectively connect the bitline 204 to the common source 216. The control logic can activate transistor 602 to selectively connect the bitline 204 to the DW signal path 606. The control logic can activate transistor 610 to selectively connect the DW signal path 606 to the signal path 614. The control logic can activate transistor 630 to selectively connect the signal path 614 to the signal path 626. The control logic can activate transistor 634 to selectively connect the signal path 614 to the signal path 638.

The control logic can activate transistor 617 to selectively connect the SA_OUT signal path 621 to the BL_SA_OUT signal path 690. The control logic can activate transistor 646 to selectively connect the signal path 614 to the TC signal path 650. The control logic can activate transistor 662 to selectively connect the TC signal path 650 to the TDC_INT signal path 666. The control logic can activate transistor 670 to selectively connect the TDC_INT signal path 666 to the signal path 674. The control logic can activate transistor 687 of sense amplifier latch 686 to selectively connect the TDC_INT signal path 666 to the SA_OUT signal path 621. The control logic can activate transistor 688 to selectively connect the TDC_INT signal path 666 to the signal path 677. The control logic can control inverter 683 to latch a sensed state of the selected memory cell in the sense amplifier latch 686. The control logic can control inverter 684 to output the latched state from the sense amplifier latch 686. The control logic can cause a pre-program verify (PPV) voltage to be stored in the sense amplifier latch 686 to sense whether the selected cell has yet reached the PPV voltage level during an SSPC-based program verify operation. The control logic can activate transistor 603 to selectively connect the TDC_INT signal path 666 to the common or ground node 607. The control logic can activate transistor 696 to selectively connect the TDC_INT signal path 666 to the DATA_TRANSFER signal path 693. The control logic can activate transistor 613 to selectively connect the signal path 611 to the common or ground node 607. The control logic can activate transistor 627 to selectively connect the signal path 625 to the common or ground node 607.

In some embodiments, the control logic of the local media controller 135 performs operations in order to transfer a program verify pass voltage (e.g., inhibit bias voltage) to the data elaborator 601 from the first latch 691. This may be performed in order to inhibit further programming due to the selected memory cells having already reached a target Vt voltage. The operations can include, for example, causing the sense node (TC) to be coupled to ground (GND), and, in response to detecting a high bit value stored in the SA latch 686, causing the program verify pass voltage (PV pass) to be transferred to the data elaborator 601 from the second latch 692.

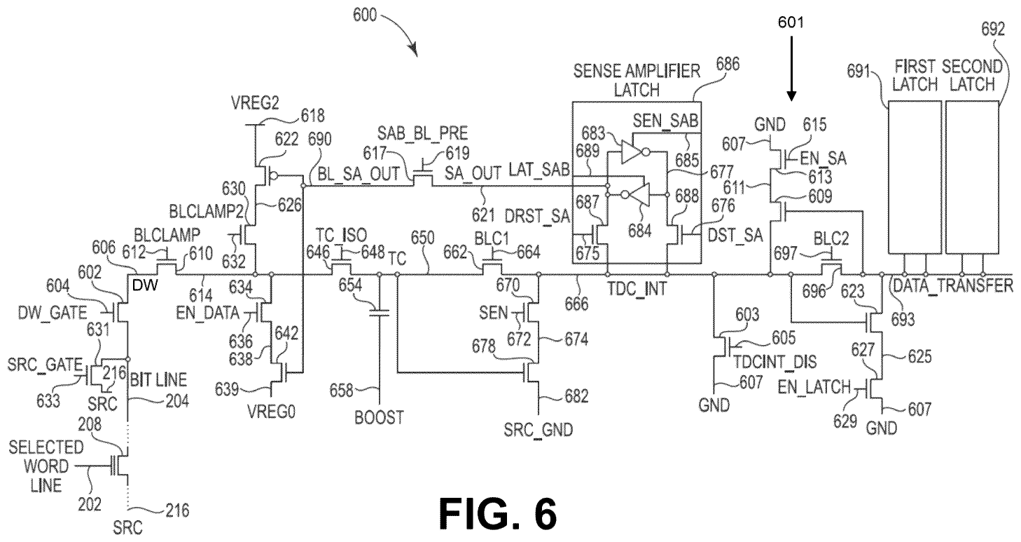

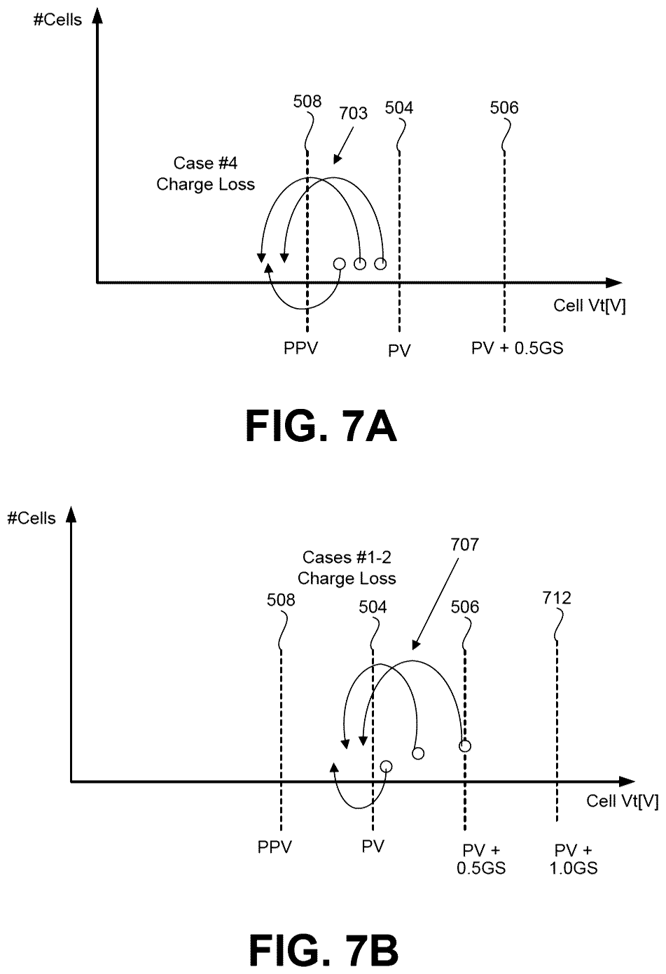

FIG. 7A is a diagrammatic illustration that depicts charge loss of memory cells that generally cause misclassification after the memory cells drop below a pre-program verify (PPV) voltage according to some embodiments. In various embodiments, memory cells will lose some charge during the suspended state before resuming programming, and will exit the suspend operation at a lower threshold voltage (Vt), which can be probabilistically misclassified in terms of being full program cells, SSPC cells, or inhibit cells.

TABLE 1

| Vt | Charge | Vt @ | VBL @ | VBL @ | Effective GS | | |
|---|---|---|---|---|---|---|---|
| before | loss at | resume | prior | resume | @ resume | Nominal Vt after | |
| suspend | cell | verify | pulse | pulse | pulse | resume pulse | Case |
| PV + | >0.5GS | PPV to PV | 0 V | VSSPC | 0.5GS | PV < Vt + 0.5GS | |
| 0.5GS | | | VSSPC | VSSPC | 0GS | PV + 0.5GS < Vt < PV + GS | 1 |
| PV+ | <0.5GS | PPV to PV | 0 V | VSSPC | 0.5GS | PV < Vt < PV + 0.5GS | |
| | | | VSSPC | VSSPC | GS | PV + 0.5GS < Vt < PV + GS | 2 |
| | >0.5GS | <PPV | 0 V | 0 V | GS | PV < Vt < PV + 0.5GS | |
| | | | VSSPC | 0 V | 1.5GS | PV + 0.5GS < Vt < PV + GS | 3 |
| PV− | >0.5GS | <PPV | 0 V | 0 V | GS | PV < Vt < PV + 0.5GS | |
| | | | VSSPC | 0 V | 1.5GS | PV + 0.5GS < Vt < PV + GS | 4 |
| PPV+ | <0.5GS | <PPV | 0 V | 0 V | GS | PV < Vt < PV + 0.5GS | |

Table 1 summarizes and classifies these different memory cells at different Vt levels relative to the PV voltage and the PPV voltage, assuming that the difference between the PV and PPV voltages is approximately a state width of a half gate-step (0.5 GS) voltage. Also, the letters “GS” alone are assumed to mean 1.0 GS. As illustrated, the first column is the cell Vt before suspend, the second column is the charge loss incurred by the memory cell(s), the third column is the Vt at performing the resume program verify operation, the fourth column is the bitline voltage (VBL) for the prior pulse, while the fifth column is the bitline voltage for the resume programming pulse, the six column is the effective gate-step voltage for the resume programming pulse, the sixth column is the nominal Vt after the resume programming pulse, and the seventh column is the identified particular case referenced in the text herein.

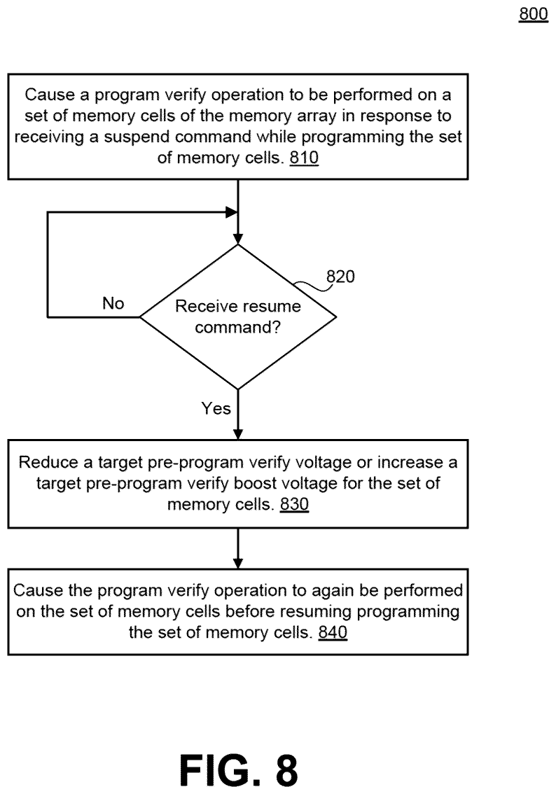

While many scenarios are illustrated in Table 1, of particular interest with reference to FIG. 7A are memory cells classified as “Case 4,” indicated by 703, which were programmed below the program verify voltage (e.g., PV−) but above the PPV voltage before the suspend, and after suspend, fell to a program state below the PPV voltage (e.g., <PPV). These Case 4 memory cells, for example, can include memory cells that had been programmed in the prior pulse with SSPC bitline voltage and lost more than a half gate-step voltage of charge in the duration of the suspended state. Such cells can end up receiving a full program pulse at resume and move by the gate-step (WL bias difference) plus 0.5 GS (SSPC removal), potentially leading these cells to be programmed beyond PV+0.5 GS, e.g., as high as PV+GS or higher. The solution to these types of misclassified memory cells can include reducing the PPV voltage or increasing the pre-program verify boost voltage for the subset of type Case 4 memory cells. In this way, the resume verify operation (performed on receipt of the resume command) can properly classify the type Case 4 memory cells as being SSPC memory cells and apply SSPC-level bias voltages, as will be discussed in more detail with reference to FIG. 8.

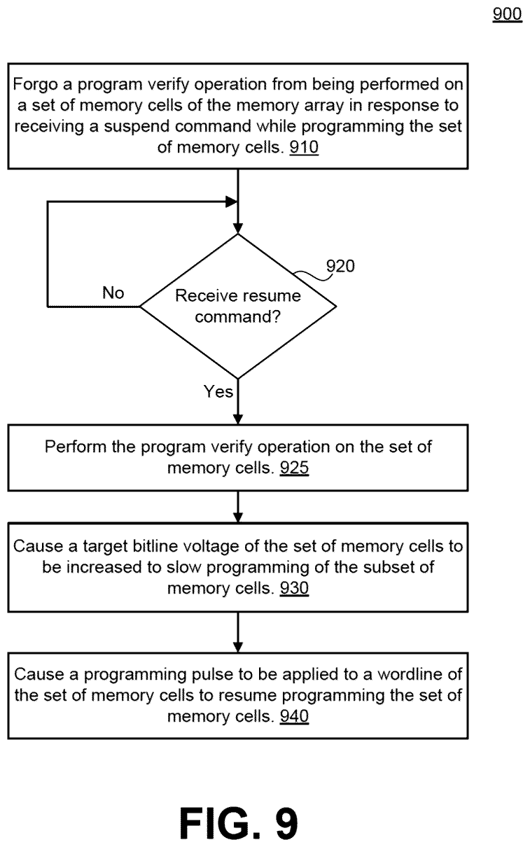

FIG. 7B is a diagrammatic illustration that depicts charge loss of memory cells that generally cause misclassification after the memory cells drop between the PPV voltage and a program verify (PV) voltage according to some embodiments. With additional reference to Table 1, this can happen if no program verify (PVY) operation is performed in response to a suspend command, e.g., as is showcased in Case 1 and Case 2. Case 1-classified and Case 2-classified memory cells will be eliminated upon performing a program verify at suspend. In FIG. 7B, these type Case 1 and Case 2 (e.g., a subset of) memory cells are indicated by 707. As can be seen, memory cells programmed above the PV voltage before suspend have now lost charge and now classified as having a Vt between the PPV voltage and the PV voltage. The solution to handling these types of misclassified memory cells at program-resume can include causing a bitline voltage of these SSPC cells to be increased to slow down programming of this subset of memory cells, which will be discussed in more detail with reference to FIG. 9. If some of these cells have already received an SSPC pulse in the prior pulse, a bitline voltage increase will more cautiously push this subset of memory cells back above the PV voltage. Otherwise, without such an increase in the bitline voltage, the memory cells could be programmed to above PV+0.5 GS, including as high as an overprogrammed voltage 712 of the PV voltage plus a full gate-step voltage (e.g., PV+1.0 GS).

FIG. 8 is a flow diagram of an example method 800 of compensating for the cells classified as per FIG. 7A so as to avoid misclassification according to some embodiments. The method 800 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 800 is performed by the local media controller 135 (or control logic) of FIGS. 1A-1B that includes instructions registers 128. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 810, a program verify operation is performed. For example, the processing logic (e.g., local media controller 135) causes a first program verify operation to be performed on a set of memory cells of the memory array of a memory device, such as memory device 130, in response to receiving a suspend command while programming the set of memory cells.

At operation 820, a determination is made. For example, the processing logic determines whether a resume command has been received and, if not, continues waiting for a resume command for the program operation associated with operation 810 to be received.

At operation 830, a modified programming scheme is implemented. For example, the processing logic, in response to receiving the resume command at operation 820, reduces a target pre-program verify voltage or increases a target pre-program verify boost voltage for the set of memory cells. In some embodiments, the set of memory cells includes memory cells within a page (e.g., associated with an UP, LP, XP or the like) that had been programmed within a gate-step voltage of the program verify voltage and lost more than a half gate-step voltage of charge during a suspend operation performed in response to the suspend command. In embodiments, reducing the target pre-program verify voltage or increasing the target pre-program verify boost voltage is performed at page buffers (such as the page buffer 600) selectively coupled to strings for a page that includes the set of memory cells. In embodiments, reducing the target pre-program verify voltage or increasing the target pre-program verify boost voltage causes the set of memory cells to be properly classified, after charge loss during a suspend operation, as having been programmed to a threshold voltage between the target pre-program verify voltage and a target program verify voltage.

In some embodiments, the target pre-program verify boost voltage may have a commensurate adjustment to the target pre-program verify voltage. For example, a positive boost_ppv voltage supplied to the BOOST node 658 (FIG. 6), after a development time, allows the memory cells, which had caused a larger sense node (TC) voltage drop, to be sensed by the sense amplifier latch 686 when the transistor 646 is opened. A larger boost_ppv voltage can allow memory cells even lower in Vt (e.g., that draw more current) to trip the sense amplifier latch 686, e.g., via the transistor 617. Thus, a higher boost_ppv voltage can equate to a larger difference between the PPV voltage and the PV voltage.

At operation 840, the program verify operation is executed. For example, the processing logic causes the program verify operation to again be performed on the set of memory cells before resuming programming the set of memory cells. In embodiments, programming the set of memory cells is performed using selective slow programming convergence (or SSPC programming), which employs the pre-program verify voltage and a program verify voltage.

In some embodiments, the method 800 can be extended to additional operations. For example, the method 800 can include causing a programming pulse to be applied to wordlines of the set of memory cells after completion of the program verify operation at resume. The method can include increasing the pre-program verify voltage (or decreasing the pre-program verify boost voltage) back to original selective slow programming convergence values for a further program verify operation after the set of memory cells are further programmed by the programming pulsc.

FIG. 9 is a flow diagram of an example method 900 of compensating for the cells classified as per FIG. 7B as to avoid voltage overshoot according to some embodiments. The method 900 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 900 is performed by the local media controller 135 (or control logic) of FIGS. 1A-1B that includes instructions registers 128. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 910, a program verify operation is not performed. For example, the processing logic (e.g., local media controller 135) can forgo a program verify operation from being performed on a set of memory cells of a memory array of a memory device (e.g., memory device 130) in response to receiving a suspend command while programming the set of memory cells. Whether to perform a program verify operation as a part of the suspend operation can be application or memory device specific, but the Case 1 and Case 2 memory cells from Table 1 may be difficult to detect without such a program verify operation upon suspend.

At operation 920, a determination is made. For example, the processing logic determines whether a resume command has been received and, if not, continues waiting for a resume command for the program operation associated with operation 910 to be received.

At operation 925, a program verify operation is performed. More specifically, the processing logic, in response to receiving the resume command, performs the program verify operation on the set of memory cells (e.g., which was referred to as program verify on resume with reference to Table 1). This program verify operation may allow the processing logic to classify at least some of the set of memory cells.

At operation 930, a modified programming scheme is implemented. For example, the processing logic can identify SSPC cells in the program verify operation, and causes a target bitline voltage for these memory cells to be increased at the resumed pulse, to slow down programming of the set of memory cells. In embodiments, these memory cells are located within a page (e.g., LP, UP, XP or the like) and are those that have lost charge from a threshold voltage (Vt) beyond program verify (PV) before suspend to between the pre-program verify voltage (PPV voltage) and the program verify voltage (PV voltage) at resume (see Case 1 and Case 2 type memory cells in Table 1). In embodiments, causing the target bitline voltage to be increased for this subset of memory cells reduces their risk of overshoot of threshold voltage from the programming pulse at resume.

At operation 940, a programming pulse is applied. For example, the processing logic causes a programming pulse to be applied to the wordline of the set of memory cells to resume programming the set of memory cells. In embodiments, programming the set of memory cells is performed using selective slow programming convergence (or SSPC programming), which employs a pre-program verify voltage and a program verify voltage.

In some embodiments, the method 900 further includes determining that the program verify operation results in the subset of memory cells being verified at the program verify voltage. The method 900 can further include causing, while a subsequent programming pulse (e.g., a second or subsequent programming pulse) is applied to the set of memory cells, the bitline voltage of the subset of memory cells to be increased to an inhibit voltage. Thus, the method 900 can return to normal SSPC-based programming after the bitline bias voltage is increased for the first programming pulse after resume.

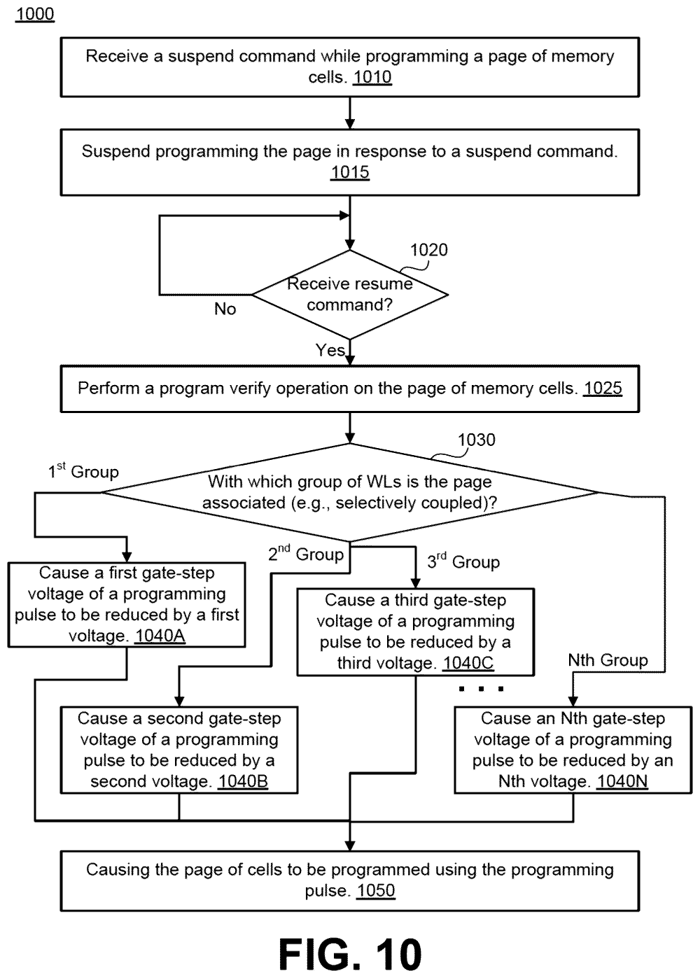

FIG. 10 is a flow diagram of an example method 1000 of selectively programming wordlines based on likelihood of charge loss or program step voltage to provide additional protection against voltage overshoot according to some embodiments. The method 1000 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 1000 is performed by the local media controller 135 (e.g., control logic) of FIGS. 1A-1B that includes instructions registers 128. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

In various embodiments, the voltage overshoot of misclassified memory cells at the subsequent pulse (after resume) is a function of the likelihood of charge loss and the program step voltage (Vpgm-step) of the programming pulse. Both of the likelihood of charge loss and the program step voltage are a function of wordline characteristics, which can vary across different WLs, and can be limited by mechanisms at each memory cell. Thus, to avoid overprogramming memory cells based on these criteria, the memory device can further vary the reduced program step voltages (also referred to gate-step voltages) applied to groups of WLs to minimize the performance impact whenever possible, e.g., according to a gate-step voltage of these memory cells. More specifically, the memory device can apply a lower reduced program step voltage to WLs that have a lower typical gate-step voltage and apply a higher reduced program step voltage to WLs that have a higher typical gate-step voltage. In embodiments, the voltage amplitude of a subsequent programming pulse during the SSPC-based programming (e.g., a second programming pulse after resume) can be restored to an original program step voltage.

At operation 1010, a suspend command is received. For example, the processing logic (e.g., the local media controller 135) receives a suspend command while programming a page of memory cells.

At operation 1015, programming is suspended. More specifically, the processing logic suspends programming the page of memory cells.

At operation 1020, a determination is made. For example, the processing logic determines whether a resume command has been received and, if not, continues waiting for a resume command for the program operation associated with operation 1010 to be received.

At operation 1025, a program verify operation is performed. For example, the processing logic, in response to receiving a resume command, performs a program verify operation on the page of memory cells, (e.g., which was referred to as program verify on resume with reference to Table 1). This program verify operation may allow the processing logic to classify (or lookup a classification of) at least some of wordlines.

At operation 1030, a determination is made. For example, the processing logic determines with which group of wordlines of a plurality of wordlines is the page of memory cells associated that is to be further programmed after receipt of the resume command. For example, being associated with the wordlines can mean that the page of memory cells is selectively coupled to a wordline of that groups of wordlines. In embodiments, the set of memory cells are associated with or a part of a page (e.g., LP, UP, XP or the like).

At operations 1040A through 1040B, different reductions in gate-step voltages (e.g., associated with SSPC programming) are made depending on which group of wordlines is identified at operation 1030 and in response to resuming programming of the page of memory cells. Thus, for example, at operation 1040A, the processing logic causes a first gate-step voltage of a programming pulse to be reduced by a first voltage in response to the page being associated with a first group of wordlines. At operation 1040B, the processing logic causes a second gate-step voltage of the programming pulse to be reduced by a second voltage in response to the page being associated with a second group of wordlines. In some embodiments, the first gate-step voltage is larger than the second gate-step voltage and the first voltage is larger than the second voltage. In other embodiments, the first gate-step voltage is smaller than the second gate-step voltage and the first voltage is smaller than the second voltage. In this way, gate-step voltage associated with particular wordlines can changed by a proportional amount of voltage.

Further, at operation 1040C, the processing logic causes a third gate-step voltage of a programming pulse to be reduced by a third voltage in response to the page being associated with a third group of wordlines. At operation 1040D, the processing logic causes an Nth gate-step voltage of the programming pulse to be reduced by an Nth voltage in response to the page being associated with an Nth group of wordlines. In some embodiments, the third gate-step voltage is larger than the Nth gate-step voltage and the third voltage is larger than the Nth voltage. In other embodiments, the third gate-step voltage is smaller than the Nth gate-step voltage and the third voltage is smaller than the Nth voltage. In this way, gate-step voltage associated with particular wordlines can changed by a proportional amount of voltage.

At operation 1050, the programming pulse is applied. More specifically, the processing logic causes the page of memory cells to be programmed using the programming pulse. The method 1000 can further include further programming the page of memory cells using a second programming pulse having an original program step voltage, e.g., and therefore returning to normal SSPC-based programming following the first programming pulse after resume.

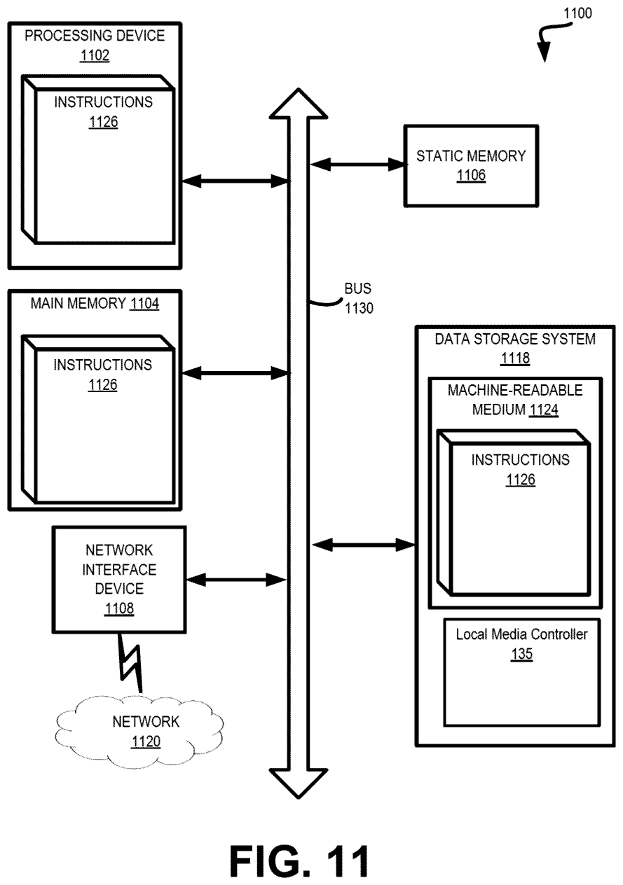

FIG. 11 illustrates an example machine of a computer system 1100 within which a set of instructions, for causing the machine to perform any one or more of the methodologies discussed herein, can be executed. In some embodiments, the computer system 1100 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the local media controller 135 of FIG. 1A), also referred to as control logic herein. In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1100 includes a processing device 1102, a main memory 1104 (e.g., read-only memory (ROM), flash memory, dynamic random access memory (DRAM) such as synchronous DRAM (SDRAM) or Rambus DRAM (RDRAM), etc.), a static memory 1110 (e.g., flash memory, static random access memory (SRAM), etc.), and a data storage system 1118, which communicate with each other via a bus 1130.

Processing device 1102 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1102 can also be one or more special-purpose processing devices such as an application specific integrated circuit (ASIC), a field programmable gate array (FPGA), a digital signal processor (DSP), network processor, or the like. The processing device 1102 is configured to execute instructions 1128 for performing the operations and steps discussed herein. The computer system 1100 can further include a network interface device 1112 to communicate over the network 1120.

The data storage system 1118 can include a machine-readable storage medium 1124 (also known as a computer-readable medium) on which is stored one or more sets of instructions 1128 or software embodying any one or more of the methodologies or functions described herein. The data storage system 1118 can further include the local media controller 135, which were previously discussed. The instructions 1128 can also reside, completely or at least partially, within the main memory 1104 and/or within the processing device 1102 during execution thereof by the computer system 1100, the main memory 1104 and the processing device 1102 also constituting machine-readable storage media. The machine-readable storage medium 1124, data storage system 1118, and/or main memory 1104 can correspond to the memory sub-system 110 of FIG. 1A.

In one embodiment, the instructions 1126 include instructions to implement functionality corresponding to a controller (e.g., the memory sub-system controller 115 of FIG. 1A). While the machine-readable storage medium 1124 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, clements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations hercin. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., non-transitory computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising memory cells; and
control logic operatively coupled with the memory array, the control logic to perform operations comprising:
causing a program verify operation to be performed on a set of memory cells of the memory array in response to receiving a suspend command while programming the set of memory cells;
one of reducing a target pre-program verify voltage or increasing a target pre-program verify boost voltage for the set of memory cells in response to receiving a resume command; and
causing the program verify operation to again be performed on the set of memory cells before resuming programming the set of memory cells.

2. The memory device of claim 1, wherein the one of reducing the pre-program verify voltage or increasing the pre-program verify boost voltage is performed at page buffers selectively coupled to strings for a page that includes the set of memory cells.

3. The memory device of claim 1, wherein programming the set of memory cells is performed using selective slow programming convergence, which employs the pre-program verify voltage and a program verify voltage.

4. The memory device of claim 1, wherein the set of memory cells includes memory cells within a page that had been programmed within a gate-step voltage of the program verify voltage and lost more than a half gate-step voltage of charge during a suspend operation performed in response to the suspend command.

5. The memory device of claim 4, wherein causing the one of the reducing of the pre-program verify voltage or the increasing the pre-program verify boost voltage causes the set of memory cells to be properly classified, after charge loss during a suspend operation, as having been programmed to a threshold voltage between the pre-program verify voltage and a program verify voltage.

6. The memory device of claim 1, wherein the operations further comprise:
causing a programming pulse to be applied to wordlines of the set of memory cells after completion of the program verify operations; and
one of increasing the pre-program verify voltage or decreasing the pre-program verify boost voltage back to original selective slow programming convergence values for a further program verify operation after the set of memory cells are further programmed by the programming pulse.

7. The memory device of claim 1, wherein the set of memory cells comprises a page of memory cells, and wherein the operations further comprise:
determining with which group of wordlines of a plurality of wordlines is the page of memory cells associated that is to be further programmed after receipt of the resume command;
in response to resuming programming the page of memory cells, one of:
causing a first gate-step voltage of a programming pulse to be reduced by a first voltage in response to the page being associated with a first group of wordlines; or
causing a second gate-step voltage of the programming pulse to be reduced by a second voltage in response to the page being associated with a second group of wordlines; and
causing the page of memory cells to be programmed using the programming pulse.

8. A memory device comprising:
a memory array comprising memory cells; and
control logic operatively coupled with the memory array, the control logic to perform operations comprising:
forgoing a program verify operation from being performed on a set of memory cells of the memory array in response to receiving a suspend command while programming the set of memory cells;
causing, in response to receiving a resume command, a target bitline voltage of the set of memory cells to be increased to slow the programming of the set of memory cells; and
causing a programming pulse to be applied to a wordline of the set of memory cells to resume programming the set of memory cells.

9. The memory device of claim 8, wherein programming the set of memory cells is performed using selective slow programming convergence, which employs a pre-program verify voltage and a program verify voltage.

10. The memory device of claim 8, wherein causing the bitline voltage to be increased for the set of memory cells reduces overshoot of charge stored within at least some of the set of memory cells due to programming by the programming pulse.

11. The memory device of claim 8, wherein the operations further comprise:
performing the program verify operation in response to receiving a resume command; and
wherein the set of memory cells include memory cells of a page that have been programmed to a voltage between a pre-program verify voltage and a program verify voltage.

12. The memory device of claim 11, wherein the operations further comprise:
determining that the program verify operation results in the set of memory cells being verified at the program verify voltage; and
causing, while a subsequent programming pulse is applied to the set of memory cells, the target bitline voltage of the set of memory cells to be increased to an inhibit voltage.

13. The memory device of claim 8, wherein the set of memory cells comprises a page of memory cells, and wherein the operations further comprise:
determining with which group of wordlines of a plurality of wordlines is the page of memory cells associated that is to be further programmed after receipt of the resume command; and
in response to resuming programming the page of memory cells, one of:
causing a first gate-step voltage of the programming pulse to be reduced by a first voltage in response to the page being associated with a first group of wordlines; or
causing a second gate-step voltage of the programming pulse to be reduced by a second voltage in response to the page being associated with a second group of wordlines.

14. A method comprising:
determining, by control logic of a memory device, with which group of wordlines of a plurality of wordlines is a page of memory cells associated that is to be further programmed after a resume command;
in response to resuming programming the page of memory cells, one of:
causing a first gate-step voltage of a programming pulse to be reduced by a first voltage in response to the page being associated with a first group of wordlines; or
causing a second gate-step voltage of the programming pulse to be reduced by a second voltage in response to the page being associated with a second group of wordlines; and
causing, by the control logic, the page of memory cells to be programmed using the programming pulse.

15. The method of claim 14, further comprising:
receiving a suspend command while programming the page of memory cells;
suspending programming the page of memory cells; and
determining that a resume command has been received.

16. The method of claim 14, wherein the first gate-step voltage is larger than the second gate-step voltage and the first voltage is larger than the second voltage.

17. The method of claim 14, wherein the first gate-step voltage is smaller than the second gate-step voltage and the first voltage is smaller than the second voltage.

18. The method of claim 14, wherein resuming programming the page of memory cells further comprises one of:
causing a third gate-step voltage of a programming pulse to be reduced by a third voltage in response to the page being associated with a third group of wordlines; or
causing an Nth gate-step voltage of the programming pulse to be reduced by an Nth voltage in response to the page being associated with an Nth group of wordlines.

19. The method of claim 18, wherein one of:
wherein the third gate-step voltage is larger than the Nth gate-step voltage and the third voltage is larger than the Nth voltage; or
wherein the third gate-step voltage is smaller than the Nth gate-step voltage and the third voltage is smaller than the Nth voltage.

20. The method of claim 14, further comprising further programming the page of memory cells using a second programming pulse having an original program step voltage.
